(19) United States
(12) Patent Application Publication
(10) Pub. No.: US 2024/0355677 A1
(43) Pub. Date: Oct. 24, 2024

(54) METHOD FOR MANUFACTURING ELECTRONIC DEVICE AND ELECTRONIC DEVICE

(71) Applicant: TDK Corporation, Tokyo (JP)

(72) Inventors: Shinji HARA, Tokyo (JP); Susumu AOKI, Tokyo (JP); Kazuya MAEKAWA, Tokyo (JP); Maiko KOKUBO, Tokyo (JP); Takahiro NAKAGAWA, Tokyo (JP)

(21) Appl. No.: 18/632,477

(22) Filed: Apr. 11, 2024

(30) Foreign Application Priority Data
Apr. 18, 2023 (JP) 2023-067813

(51) Int. Cl. H01L 21/78; B32B 3/30; B32B 9/04; B81C 1/00; H01L 21/683; H04N 25/21; H04N 25/79

(52) U.S. Cl. CPC H01L 21/78; B32B 3/30; B32B 9/04; B81C 1/00904; H01L 21/6836; B32B 2457/00; H01L 2221/68336; H04N 25/21; H04N 25/79

(57) ABSTRACT

A method for manufacturing an electronic device includes a stretchable member attachment step of attaching stretchable member 21 to first substrate 2 on which second substrate 3 is stacked, a first modification line formation step of forming one or more first modification lines 22 by irradiating the first substrate 2 with a laser beam, and a dividing step of stretching the stretchable member 21 to divide the first substrate 2 along the one or more first modification lines 22.

### FIELD

The present application is based on, and claims priority from, JP2023-067813, filed on Apr. 18, 2023, the disclosure of which is hereby incorporated by reference herein in its entirety.

The present disclosure relates to an electronic device manufacturing method and an electronic device.

### BACKGROUND

In the manufacturing process of electronic devices, it is common to form areas on a wafer that will become a plurality of chips and then cut the wafer into individual chips. JP 3,624,909 B discloses a method of cutting a wafer into individual chips. Specifically, a modification area is formed by irradiating a wafer with a laser beam, attaching a stretchable film to the wafer on which the modification area has been formed, and cutting the wafer starting from the modification area by stretching the film.

### SUMMARY

In recent years, stacked substrates in which a plurality of wafers are joined have been used in fields such as MEMS (Micro electro mechanical Systems). Even in such stacked substrates, a stacked substrate may be cut and divided into individual chips. When cutting a stacked substrate in which wafers are stacked, a blade dicing method or a laser ablation method is used. However, since the blade dicing method and the laser ablation method involve cutting allowances, the cutting allowance portion of the substrate is wasted.

It is desirable to provide a method for manufacturing an electronic device that reduces the need for cutting allowances in a stacked substrate in which a plurality of substrates is stacked.

According to one aspect of the present disclosure, a method for manufacturing an electronic device includes a stretchable member attachment step of attaching a stretchable member to a first substrate on which a second substrate is stacked, a first modification line formation step of forming at least one first modification line by irradiating the first substrate with a laser beam, and a dividing step of stretching the stretchable member to divide the first substrate along the at least one first modification line.

### BRIEF DESCRIPTION OF THE DRAWINGS

FIG. 1 is a schematic cross-sectional view showing an infrared sensor in a first embodiment;

FIGS. 2A to 2D are cross-sectional views showing a method of manufacturing an infrared sensor in a first embodiment;

FIG. 3 is a plan view of a stacked substrate in the first embodiment;

FIG. 4A is a plan view of a stacked substrate in a second embodiment;

FIGS. 4B and 4C are cross-sectional views of a stacked substrate in the second embodiment;

FIG. 5A is a plan view of a stacked substrate in a third embodiment;

FIGS. 5B and 5C are cross-sectional views of a stacked substrate in the third embodiment;

FIG. 6A is a plan view of a multilayer substrate in a fourth embodiment;

FIGS. 6B and 6C are cross-sectional views of a stacked substrate in the fourth embodiment;

FIG. 7A is a plan view of a stacked substrate in a fifth embodiment;

FIGS. 7B and 7C are cross-sectional views of a stacked substrate in the fifth embodiment;

FIG. 8A is a plan view of a stacked substrate in a sixth embodiment;

FIG. 8B is a cross-sectional view of a stacked substrate in the sixth embodiment;

FIG. 9A is a plan view of a stacked substrate in a seventh embodiment;

FIGS. 9B and 9C are cross-sectional views of a stacked substrate in the seventh embodiment;

FIG. 10A is a plan view of a multilayer substrate in a modification of the fourth embodiment;

FIG. 10B is a cross-sectional view of a stacked substrate in the modification of the fourth embodiment;

FIG. 11A is a plan view of a stacked substrate in a modification of the seventh embodiment; and

FIG. 11B is a cross-sectional view of a stacked substrate in the modification of the seventh embodiment.

### DETAILED DESCRIPTION

Some embodiments of the method for manufacturing an electronic device of this disclosure are described below with reference to the drawings. In the following description and drawings, the X-direction and the Y-direction are parallel to the principal surfaces of first substrate 2 and second substrate 3. The principal surfaces are surfaces of first substrate 2 and second substrate 3 that face each other. The X-direction and the Y-direction are perpendicular to each other. Further distinctions of the X-direction may be referred to as the +X-direction and the −X-direction. The Z-direction is a direction perpendicular to the X-direction and the Y-direction, and is perpendicular to the principal surfaces of first substrate 2 and second substrate 3 or the direction in which first substrate 2 and second substrate 3 are stacked. In each embodiment below, a method for manufacturing infrared sensor 1 will be described as an example of the method for manufacturing an electronic device, but the electronic device is not limited to infrared sensor 1.

### First Embodiment

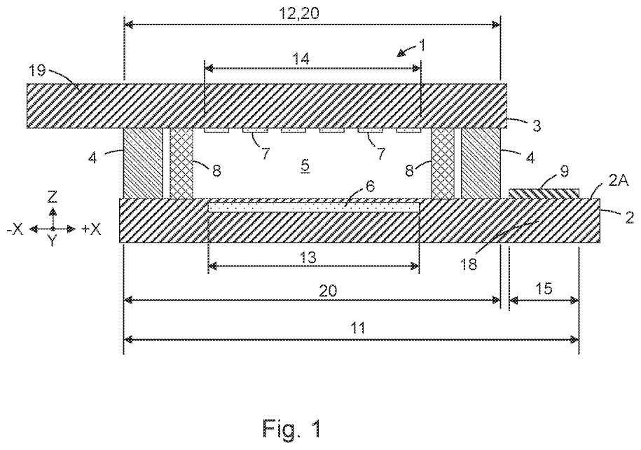

FIG. 1 is a schematic cross-sectional view showing infrared sensor 1. Infrared sensor 1 is mainly used as an image sensor of an infrared camera. Infrared cameras can be used as night vision scopes and night vision goggles in dark places, and can also be used to measure the temperature of people and objects. Infrared sensor 1 has first substrate 2 and second substrate 3 that are arranged to face each other, and side walls 4 that connect first substrate 2 and second substrate 3. Side walls 4 may be formed integrally with either first substrate 2 or second substrate 3 or may be members separate from first substrate 2 and second substrate 3. Side walls 4 and first substrate 2 and/or second substrate 3 can be bonded using a bonding material such as solder.

First substrate 2 and second substrate 3 are mainly formed of silicon substrates, and an insulating film covering circuit parts and the like is formed on the silicon substrates. Inner space 5, which is sealed, is formed by first substrate 2, second substrate 3, and side walls 4. A plurality of thermistor elements 7 that function as sensing parts of infrared sensors 1 is provided in inner spaces 5. The plurality of thermistor elements 7 form a two-dimensional lattice array consisting of a plurality of rows extending in the X-direction and a plurality of columns extending in the Y-direction. Inner spaces 5 are under negative pressure or are vacuums. Thereby, gas convection in inner spaces 5 is prevented or reduced, and thermal influence on thermistor elements 7 can be reduced.

First substrate 2 includes circuit part 6 such as a ROIC (Readout IC). Second substrate 3 supports the plurality of thermistor elements 7. First substrate 2 and second substrate 3 each include a wiring part (not shown), and in the following description, it is assumed that circuit part 6 includes a wiring part of first substrate 2 and that thermistor element 7 includes a wiring part of second substrate 3. First substrate 2 and second substrate 3 are connected by a plurality of electrical connection members 8. Electrical connection members 8 are pillar-shaped conductors and can be made, for example, by plating. Thermistor elements 7 are electrically connected to circuit parts 6 via electrical connection members 8. At least one pad 9 for inputting/outputting control signals, output signals, etc. of thermistor element 7 is formed outside side walls 4 of first substrate 2, that is, outside inner space 5. Pad 9 is formed on principal surface 2A of first substrate 2 (the surface of first substrate 2 on the second substrate 3 side). As will be described later, the position and number of pads 9 are not limited.

In the following description, elements and members related to the functions of infrared sensor 1, such as circuit part 6, thermistor element 7, and pad 9, are referred to as functional parts. The structure-forming inner space 5 of infrared sensor 1, that is, a part of first substrate 2, a part of second substrate 3, and side walls 4 constituting the structure-forming inner space 5 are also an example of functional parts. The functional parts that are provided depend on the type of electronic device. When the electronic device is a MEMS, movable parts may be provided as functional parts.

The area where circuit part 6 of each infrared sensor 1 is formed is referred to as circuit area 13, the area where thermistor element 7 of each infrared sensor 1 is formed is referred to as thermistor element area 14, and the area where at least one pad 9 is formed is referred to as pad area 15. Circuit area 13 and pad area 15 are provided on first substrate 2, and thermistor element area 14 is provided on second substrate 3. In first substrate 2 and second substrate 3, the portion where a structure that forms inner space 5 of infrared sensor 1 is formed is referred to as inner space formation area 20. Inner space formation area 20 is provided on each of first substrate 2 and second substrate 3. In first substrate 2, inner space formation area 20 corresponds to an area surrounded by lines along which the outer peripheral portions of side walls 4 are in contact with first substrate 2. In second substrate 3, inner space formation area 20 corresponds to an area surrounded by lines along which the outer peripheral portions of side walls 4 are in contact with second substrate 3.

For each infrared sensor 1 on first substrate 2, the smallest continuous area that includes all of the functional parts is referred to as first functional part formation area 11, and for each infrared sensor 1 on second substrate 3, the smallest continuous area that includes all of the functional parts is referred to as second functional part formation area 12. As shown in FIG. 1, in this embodiment, first functional part formation area 11 corresponds to the combined area of inner space formation area 20 and pad area 15, and second functional part formation area 12 corresponds to inner space formation area 20.

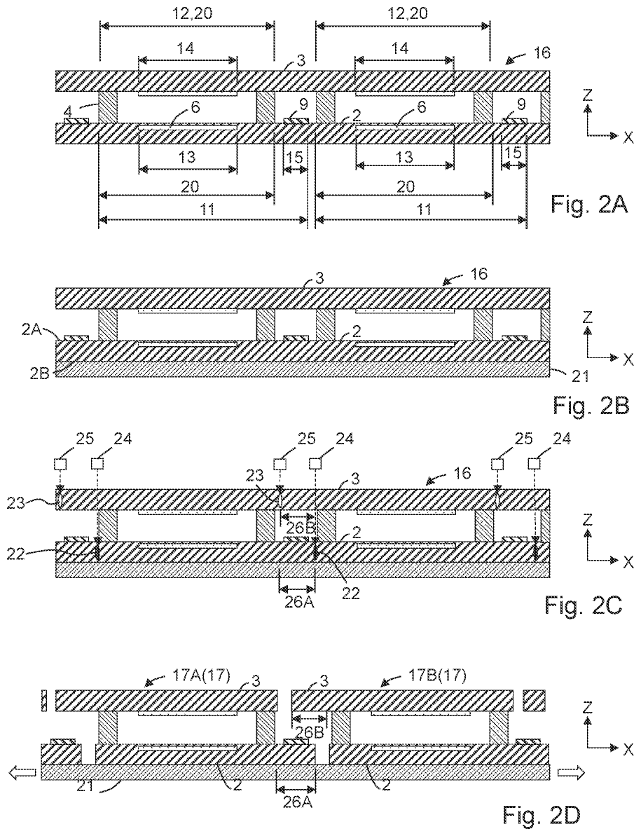

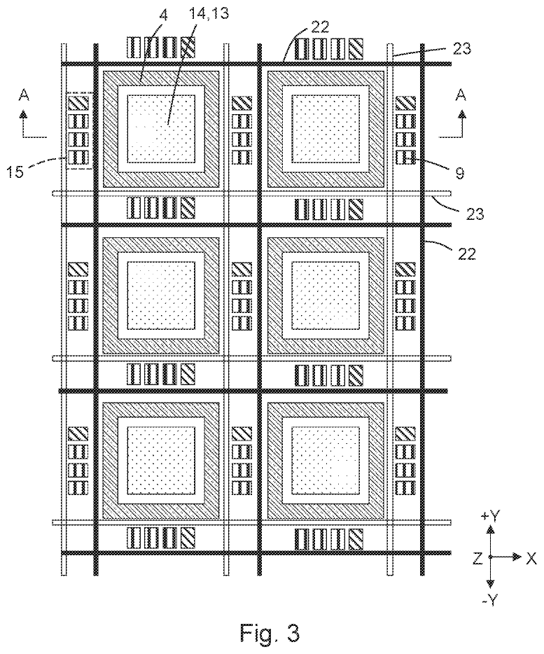

A method of manufacturing infrared sensor 1 according to the first embodiment will be described with reference to FIGS. 2A to 2D and FIG. 3. FIG. 2 is a step diagram showing a part of the method for manufacturing infrared sensor 1 and shows a cross section taken along line A-A in FIG. 3. FIG. 3 shows a plan view of stacked substrate 16 in which first substrate 2 and second substrate 3 are stacked. For convenience, FIG. 3 shows elements formed on first substrate 2 and second substrate 3 and elements located between first substrate 2 and second substrate 3 on one plane. Since infrared sensor 1 is mainly manufactured in a wafer process, first substrate 2 and second substrate 3 are wafers before being divided. Therefore, first substrate 2 has a plurality of first functional part formation areas 11, and second substrate 3 has a plurality of second functional part formation areas 12. In a plan view from the Z-direction, circuit area 13, thermistor element area 14, and pad area 15 all have rectangular shapes. For convenience, FIG. 3 shows circuit area 13 and thermistor element area 14 coinciding with each other in a plan view from the Z-direction, but circuit area 13 and thermistor element area 14 may also have different sizes, shapes, and positions as seen in a plan view from the Z-direction.

First, as shown in FIG. 2A, stacked substrate 16 in which first substrate 2 and second substrate 3 are stacked is manufactured. A plurality of circuit areas 13 and a plurality of pad areas 15 are formed on first substrate 2, and a plurality of thermistor element areas 14 are formed on second substrate 3. The number of circuit areas 13 and thermistor element areas 14 is equal to the number of infrared sensors 1 to be manufactured from stacked substrate 16. As shown in FIG. 3, each circuit area 13 is combined with two pad regions 15. In an area that is to become one chip (in FIG. 3, an area that is surrounded by two first modification lines 22 extending in the X-direction and adjacent to each other and two first modification lines 22 extending in the Y-direction and adjacent to each other), two pad areas 15 are provided so as to face, of the four peripheral sides of circuit area 13 of first substrate 2, two adjacent sides. Each pad area 15 includes a plurality of pads 9. In FIG. 3, although each pad area 15 includes four pads 9, the number of pads 9 in each pad area 15 is not limited.

Next, as shown in FIG. 2B, stretchable member 21 is attached to first substrate 2 on which second substrate 3 is stacked (stretchable member attachment step). Stretchable member 21 is attached to back surface 2B that is opposite principal surface 2A of first substrate 2. A resin film can be used as stretchable member 21, but material is not limited as long as it has stretchability. Stretchable member 21 has its outer circumferential portion supported by a support member (not shown), but the portions of stretchable member 21 other than the outer circumferential portion are not supported or constrained by other members. In other words, no member is in contact with the back surface that is opposite the surface of stretchable member 21 that is in contact with first substrate 2.

Next, as shown in FIGS. 2C and 3, at least one (in this embodiment, a plurality of) first modification line 22 is formed (first modification line formation step). Specifically, while moving first laser beam irradiation unit 24 in the X-direction and the Y-direction, first laser beam irradiation unit 24 irradiates first substrate 2 with a laser beam, and a plurality of first modification lines 22 extending in the X-direction and a plurality of first modification lines 22 extending in the Y-direction are formed. Further, second substrate 3 is irradiated with a laser beam to form at least one (in this embodiment, a plurality of) second modification line 23 (second modification line formation step). Specifically, while moving second laser beam irradiation unit 25 in the X-direction and the Y-direction, second laser beam irradiation unit 25 irradiates second substrate 3 with a laser beam to form a plurality of second modification lines 23 extending in the X-direction and a plurality of second modification lines 23 extending in the Y-direction. Either of the first modification line formation step and the second modification line formation step may be performed first, or the two steps may be performed simultaneously. Further, the same laser beam irradiation unit may be used for both first laser beam irradiation unit 24 and second laser beam irradiation unit 25.

In a plan view from the Z-direction, a plurality of first modification lines 22 and a plurality of second modification lines 23 are formed at different positions from each other. This makes it easy, for example, to perform the first modification line formation step and the second modification line formation step at the same time.

The laser beam is applied so as to focus on a position of predetermined depth (Z-direction position) of first substrate 2 or second substrate 3. In the vicinity of the position of focus of the laser beam, the insides of first substrate 2 and second substrate 3 are modified, and an area is formed in which strength against tensile force is lower than that of the surrounding areas. That is, first modification line 22 and second modification line 23 are linear areas in which strength against tensile force is lower than the surrounding areas.

In the first modification line formation step, a plurality of first modification lines 22 may be formed by irradiating first substrate 2 with laser light from the second substrate 3 side. It is also possible to irradiate first substrate 2 with laser light through stretchable member 21, but stretchable member 21 made of resin or the like absorbs a part of the laser light and therefore reduces the laser light intensity that enters first substrate 2. In this embodiment, a laser beam having a wavelength that is transparent to second substrate 3 is used to transmit the laser beam through second substrate 3 and thus irradiate first substrate 2 with the laser beam. For example, laser light with a wavelength of 0.8 to 15 μm passes through a silicon substrate and is moderately absorbed by the silicon substrate. Using a laser beam of such a wavelength, the laser beam is transmitted through second substrate 3, which is a silicon substrate, and is applied such that the laser beam is focused within first substrate 2, which is a silicon substrate. Thus, first modification line 22 can be formed on first substrate 2. In this case, since the laser beam is not focused within second substrate 3, the interior of second substrate 3 is hardly modified. When forming the plurality of second modification lines 23, the second substrate 3 may be irradiated with the laser beam from the side of second substrate 3 that is opposite to the side facing first substrate 2.

Next, as shown in FIG. 2D, stretchable member 21 is stretched to divide first substrate 2 by at least one (in this embodiment, a plurality of) first modification line 22, and at the same time, to divide second substrate 3 by at least one (in this embodiment, a plurality of) second modification line 23 (dividing step). The direction in which the stretching force is applied to stretchable member 21 is not limited as long as stretchable member 21 stretches at least in the X-direction and the Y-direction. First substrate 2 is divided along a plurality of first modification lines 22 while being supported by stretchable member 21. Second substrate 3 is divided along a plurality of second modification lines 23. As a result, first substrate 2 is divided in the X-direction and the Y-direction, second substrate 3 is also divided in the X-direction and the Y-direction, and stacked substrate 16 is thus divided in two directions, the X-direction and the Y-direction. Each portion of the stacked substrate 16 divided in this manner becomes chip 17 of an individual infrared sensor 1. Although not shown, each chip 17 is then separated from stretchable member 21.

In this embodiment, pad area 15 is formed on the surface of first substrate 2 on the second substrate 3 side. Therefore, as can be understood from FIG. 2A, in a plan view from the Z-direction, the length that each first functional part formation area 11 occupies in the X-direction (a direction perpendicular to relevant first modification line 22) is greater than the length that each second functional part formation area 12 occupies in the X-direction. Here, each first functional part formation area 11 is the smallest continuous area that includes circuit area 13, pad area 15, and inner space formation area 20, and each second functional part formation area 12 is the smallest continuous area that includes thermistor element area 14 and inner space formation area 20. Although not shown in the drawings, in a plan view from the Z-direction, the length that the plurality of first functional part formation areas 11 occupy in the Y-direction (a direction perpendicular to relevant first modification line 22) is greater than the length that the plurality of second functional part formation areas 12 occupy in the Y-direction. In other words, the number of infrared sensors 1 manufactured from stacked substrate 16 is determined by the arrangement of the functional parts of first substrate 2.

Here, a case will be considered in which first substrate 2 is divided by blade dicing or laser ablation dicing that will be described later. Blade dicing is a method of cutting a substrate with a blade, and laser ablation is a method of cutting a substrate by melting and vaporizing the substrate material. In blade dicing, the area corresponding to the width of the blade is the cutting allowance, and in laser ablation dicing, the area in which the substrate material melts and evaporates is the cutting allowance. In this case, it is necessary to arrange first functional part formation areas 11 on first substrate 2 while considering the cutting allowance, and the number of infrared sensors 1 manufactured from stacked substrate 16 may be restricted because of this cutting allowance.

In the first and second modification line formation steps, the laser beam does not melt first and second substrates 2 and 3 by heat generation, but rather forms areas that are more fragile than the surroundings inside first and second substrates 2 and 3. Since first and second substrates 2 and 3 are divided by cracking along first modification lines 22 and second modification lines 23, almost no cutting allowance is generated in the dividing step. Therefore, it becomes easier to increase the number of infrared sensors 1 manufactured from stacked substrate 16.

The length that each second functional part formation area 12 of second substrate 3 occupies in the X-direction is shorter than the length that each first functional part formation areas 11 of first substrate 2 occupies in the X-direction. In addition, the length that each second functional part formation area 12 of second substrate 3 occupies in the Y-direction is shorter than the length that each first functional part formation area 11 of first substrate 2 occupies in the Y-direction. Therefore, it is unlikely that the number of infrared sensors 1 manufactured from stacked substrate 16 can be increased by forming second modification lines 23. However, since blade dicing and laser ablation dicing are not required, fragments resulting from blade dicing and melted parts resulting from laser ablation dicing are not generated. Fragments resulting from blade dicing and melted parts resulting from laser ablation dicing may cause contamination of the environment around first substrate 2 and second substrate 3. In this embodiment, it is easy to maintain a clean environment around first substrate 2 and second substrate 3, and adverse effects such as adhesion of fine particles to first substrate 2 and second substrate 3 are therefore less likely to occur.

As shown in FIGS. 2C, 2D, and 3, in the dividing step, portion 26A between one first modification line 22 and one second modification line 23 as seen in a plan view of first substrate 2 from the Z-direction becomes a part of one chip 17A, and portion 26B between one first modification line 22 and one second modification line 23 as seen in a plan view from the Z-direction of the second substrate 3 becomes a part of another chip 17B. As shown in FIG. 1, in infrared sensor 1 formed in this way, first substrate 2 has first projecting portion 18 that, as seen from a plan view from the Z-direction, projects from second substrate 3 in the +X-direction (an example of the first direction), and second substrate 3 has second projecting portion 19 that projects from first substrate 2 in a direction opposite to the +X-direction (−X-direction). As can be understood from FIG. 3, similar to the X-direction, first substrate 2 has first projecting portion 18 that, as seen from a plan view from the Z-direction, projects from second substrate 3 in the −Y-direction (an example of the first direction), and second substrate 3 has second projecting portion 19 that projects from first substrate 2 in a direction opposite to the −Y-direction (+Y-direction). A functional part is formed in at least one of first projecting portion 18 and second projecting portion 19. In this embodiment, surface 2A of first projecting portion 18 on the second substrate 3 side has pad area 15. When chips 17 are cut out from stacked substrate 16, unnecessary portions of first substrate 2 and second substrate 3 are not generated between chips 17, so there is no need to remove or dispose of the unnecessary portions, and the manufacturing process of infrared sensor 1 is therefore simplified. Furthermore, since at least a portion (in this embodiment, the entirety) of pad area 15 does not overlap with second substrate 3 as seen in a plan view from the Z-direction in chips 17 of this embodiment, wire bonding or the like to pads 9 formed in pad areas 15 can be easily performed.

### Second Embodiment

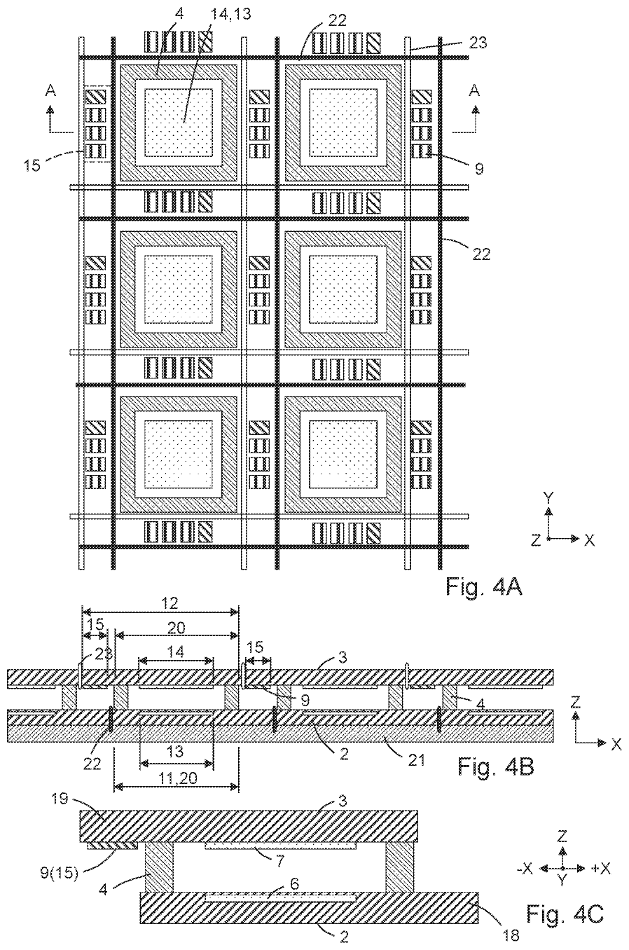

A method of manufacturing infrared sensor 1 according to the second embodiment will next be described. Explanations regarding steps and effects that are the same as those in the first embodiment is here omitted. FIG. 4A is a plan view of stacked substrate 16 in which first substrate 2 and second substrate 3 are stacked, FIG. 4B is a cross-sectional view taken along line A-A in FIG. 4A, and FIG. 4C is a cross-sectional view of one infrared sensor 1 cut out from stacked substrate 16. In FIG. 4B, for convenience, first modification lines 22 and second modification lines 23 are shown as lines longer than the thicknesses of first and second substrates 2 and 3, respectively. For convenience, FIGS. 4B and 4C are cross-sectional views along the X-direction, but this representation also applies to cross-sectional views along the Y-direction. Unlike the first embodiment, pad areas 15 are provided on second substrate 3 on the first substrate 2 side. Therefore, each first functional part formation area 11 is the smallest continuous area that includes circuit area 13 and inner space formation area 20, and each second functional part formation area 12 is the smallest continuous area that includes thermistor element area 14, pad area 15, and inner space formation area 20. In an area that becomes one chip, two pad areas 15 are provided facing two adjacent sides of the four peripheral surfaces of thermistor element area 14 of second substrate 3. In a plan view from the Z-direction, the length that each second functional part formation area 12 occupies in the X-direction (a direction perpendicular to relevant second modification line 23) is greater than the length that each first functional part formation area 11 occupies in the X-direction. In addition, in a plan view from the Z-direction, the length that each second functional part formation area 12 occupies in the Y-direction (a direction perpendicular to relevant second modification line 23) is greater than the length that each first functional part formation area 11 occupies in the Y-direction.

Also, in the dividing step in this embodiment, a portion between one first modification line 22 and one second modification line 23 as seen from a plan view from the Z-direction of first substrate 2 becomes a part of one chip 17, and a portion between one first modification line 22 and one second modification line 23 as seen from a plan view from the Z-direction of the second substrate 3 becomes a part of another chip 17. Infrared sensor 1 formed in this manner has a configuration similar to that of the first embodiment except that pad area 15 is provided on the surface of second projecting portion 19 on the first substrate 2 side of second substrate 3. As seen from a plan view from the Z-direction, at least a portion (in this embodiment, the entirety) of pad area 15 in infrared sensor 1 (chip 17) of this embodiment does not overlap with first substrate 2, and wire bonding or the like to pads 9 formed in pad areas 15 can therefore be easily performed.

### Third Embodiment

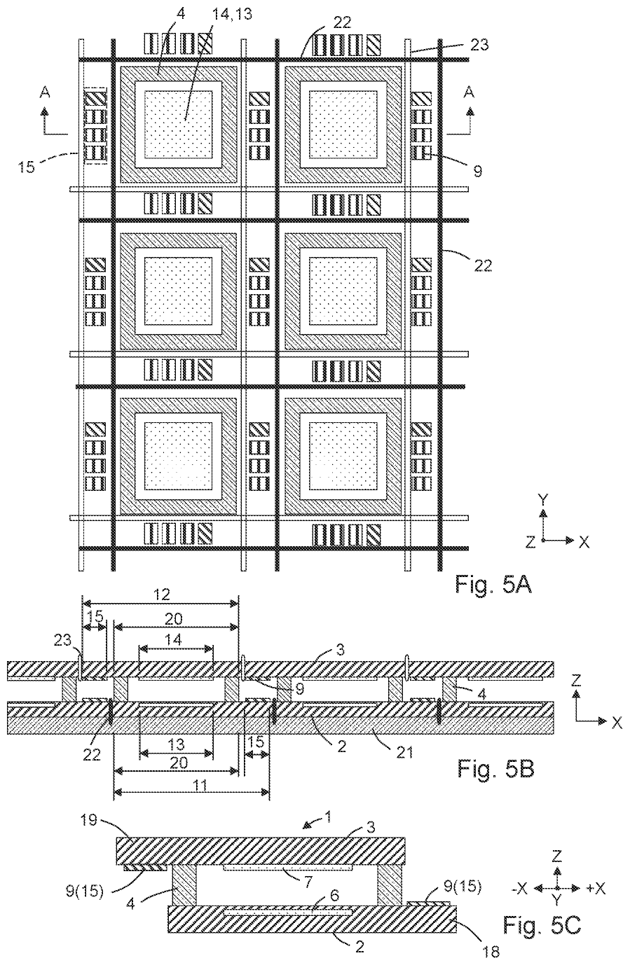

A method of manufacturing infrared sensor 1 according to the third embodiment will next be described. Explanations regarding steps and effects that are the same as those in the first and second embodiments is here omitted. FIG. 5A is a plan view of stacked substrate 16 in which first substrate 2 and second substrate 3 are stacked, FIG. 5B is a cross-sectional view taken along line A-A in FIG. 5A, and FIG. 5C is a cross-sectional view of one infrared sensor 1 cut out from stacked substrate 16. For convenience, FIGS. 5B and 5C are cross-sectional views along the X-direction, but these representations similarly apply to cross-sectional views along the Y-direction. In this embodiment, pad areas 15 are provided on first substrate 2 and second substrate 3. Therefore, in a plan view from the Z-direction, the configuration of first and second functional part formation areas 11 and 12 determines which of each first functional part formation area 11 and each second functional part formation area 12 occupies a longer length in the X-direction (or Y-direction). However, in this embodiment, the formation of first modification lines 22 and second modification lines 23 facilitates increasing the number of infrared sensors 1 manufactured from stacked substrate 16 regardless of which length is longer. In an area that becomes one chip, two of the four pad areas 15 are provided facing two adjacent sides among the four peripheral sides of circuit area 13 of first substrate 2, and the remaining two pad areas 15 are provided facing two adjacent sides among the four peripheral sides of thermistor element area 14 of second substrate 3. Note that in this embodiment, pad areas 15 formed on second substrate 3 overlie pad areas 15 formed on first substrate 2, with the result that only one set of pad areas 15 is visible in FIG. 5A.

In addition, the dividing step in this embodiment causes the portion of first substrate 2 between one first modification line 22 and one second modification line 23 as seen in a plan view from the Z-direction to become a part of one chip 17, and the portion of second substrate 3 between the one first modification line 22 and the one second modification line 23 as seen in a plan view from the Z-direction become a part of another chip 17. Infrared sensor 1 formed in this manner has a configuration similar to that of the first embodiment except that pad areas 15 are provided on both the surface of first projecting portion 18 on the second substrate 3 side of first substrate 2 and on the surface of second projecting portion 19 on the first substrate 2 side of second substrate 3. In infrared sensor 1 (chip 17) of this embodiment, at least a portion (in this embodiment, the entirety) of pad areas 15 of first projecting portion 18 does not overlie second substrate 3 as seen in a plan view from the Z-direction and at least a portion (in this embodiment, the entirety) of pad areas 15 of second projecting portion 19 does not overlie first substrate 2, and as a result, wire bonding or the like to pads 9 formed in pad areas 15 can be easily performed.

### Fourth Embodiment

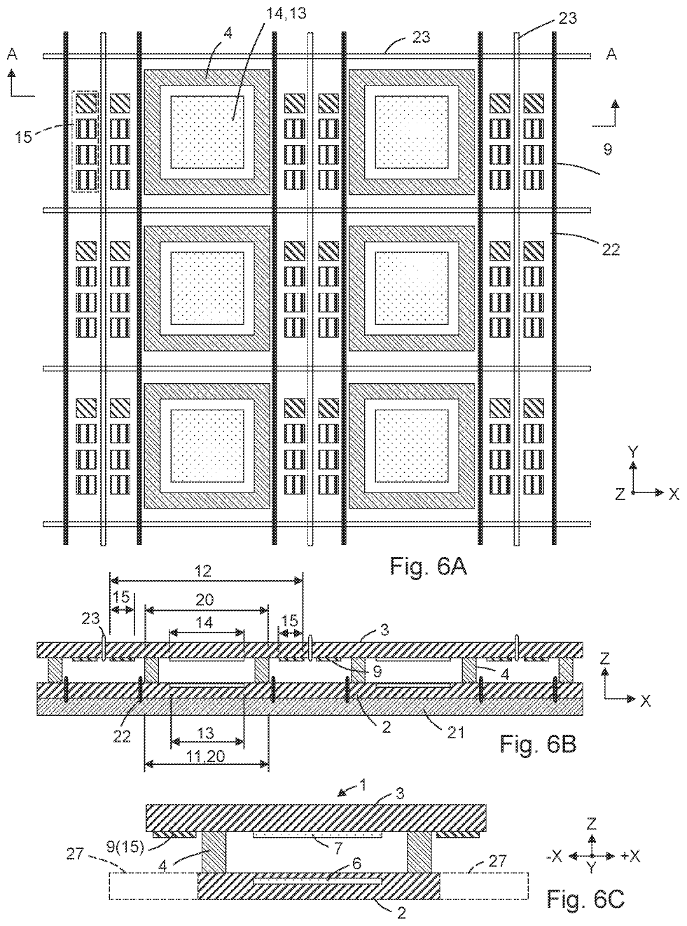

A method of manufacturing infrared sensor 1 according to the fourth embodiment will next be described. Explanations regarding steps and effects that are the same as those in the first embodiment is here omitted. FIG. 6A is a plan view of stacked substrate 16 in which first substrate 2 and second substrate 3 are stacked, FIG. 6B is a cross-sectional view taken along line A-A in FIG. 6A, and FIG. 6C is a cross-sectional view of one infrared sensor 1 cut out from stacked substrate 16. In a plan view from the Z-direction, first modification line 22 extending in the X-direction coincides with second modification line 23, and as a result, only second modification line 23 is shown in FIG. 6A. First substrate 2 has a plurality of first functional part formation areas 11, and second substrate 3 has a plurality of second functional part formation areas 12. Pad areas 15 are provided on the first substrate 2 side of second substrate 3. Of the four peripheral sides of thermistor element area 14 of second substrate 3, two pad areas 15 are provided so as to face two sides that are opposite each other in the X-direction. Therefore, each first functional part formation area 11 is the smallest continuous area that includes circuit area 13 and inner space formation area 20, and each second functional part formation area 12 is the smallest continuous area that includes thermistor element area 14, two pad areas 15, and inner space formation area 20. First functional part formation area 11 coincides with inner space formation area 20. In a plan view from the Z-direction, the length that each second functional part formation area 12 occupies in the X-direction (a direction perpendicular to relevant second modification line 23) is greater than the length that each first functional part formation area 11 occupies in the X-direction. In a plan view from the Z-direction, the length that each second functional part formation area 12 occupies in the Y-direction is the same as the length that each first functional part formation area 11 occupies in the Y-direction.

In this embodiment, formation of second modification line 23 on second substrate 3 eliminates the need for cutting allowance for second substrate 3, and the number of infrared sensors 1 manufactured from stacked substrate 16 can be easily increased. Since first and second modification lines 22 and 23 are formed on first and second substrates 2 and 3, respectively, fragments and melted parts of first and second substrates 2 and 3 are not generated. Furthermore, in this embodiment, for each infrared sensor 1, first modification lines 22 are formed on both sides in the X-direction of first functional part formation area 11 of first substrate 2. For this reason, the number of one or more (in this embodiment, more than one) first modification lines 22 extending in the Y-direction is greater than the number of one or more (in this embodiment, more than one) second modification lines 23 extending in the Y-direction. Further, as shown in FIG. 6C, portions 27 of first substrate 2 that are not used as infrared sensor 1 are generated on the sides of infrared sensor 1 in the X-direction. Since these portions 27 are held by stretchable member 21 after the dividing step, portions 27 can be easily removed.

### Fifth Embodiment

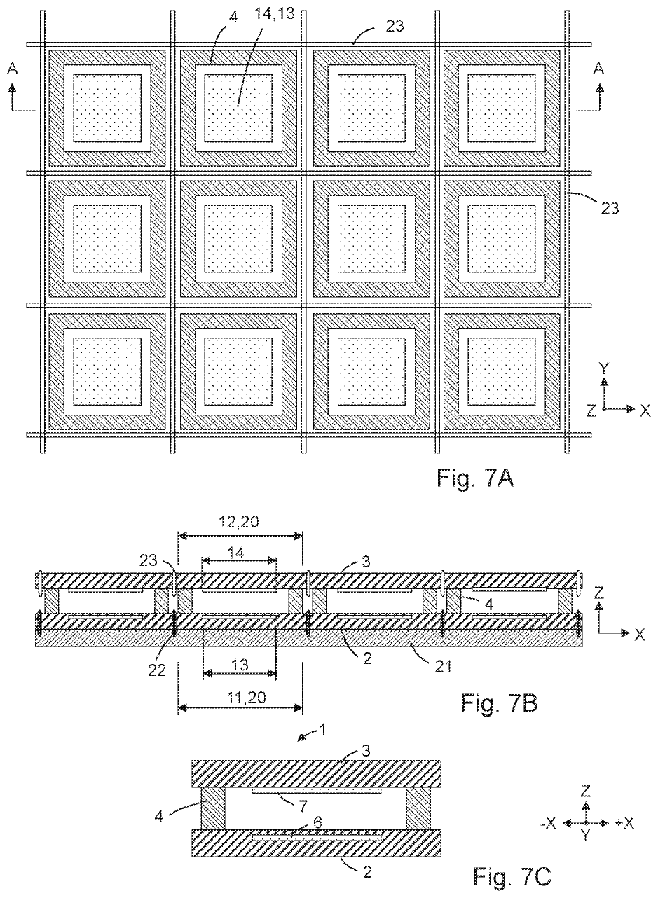

A method of manufacturing infrared sensor 1 according to the fifth embodiment will next be described. Explanations regarding steps and effects that are the same as those in the first embodiment is here omitted. FIG. 7A is a plan view of stacked substrate 16 in which first substrate 2 and second substrate 3 are stacked, FIG. 7B is a cross-sectional view taken along line A-A in FIG. 7A, and FIG. 7C is a cross-sectional view of one infrared sensor 1 cut out from stacked substrate 16. For convenience, FIGS. 7B and 7C are cross-sectional views along the X-direction, but these representations similarly apply to cross-sectional views along the Y-direction. In a plan view from the Z-direction, first modification lines 22 coincide with second modification lines 23 in both the X-direction and the Y-direction, and only second modification lines 23 are shown in FIG. 7A. Stacked substrate 16 of this embodiment is similar to the fourth embodiment with the exception that pad areas 15 are not provided. The formation of first modification lines 22 and second modification lines 23 in this embodiment facilitates increasing the number of infrared sensors 1 manufactured from stacked substrate 16. Further, in this embodiment, the formation of first modification lines 22 at the same positions as second modification lines 23 as seen in a plan view from the Z-direction facilitates the use of a single laser beam irradiation unit as first laser beam irradiation unit 24 and second laser beam irradiation unit 25. Since first modification lines 22 and second modification lines 23 located at the same positions can be formed by simply changing the focusing position of the laser beam, the process of moving first laser beam irradiation unit 24 and second laser beam irradiation unit 25 can also be simplified.

### Sixth Embodiment

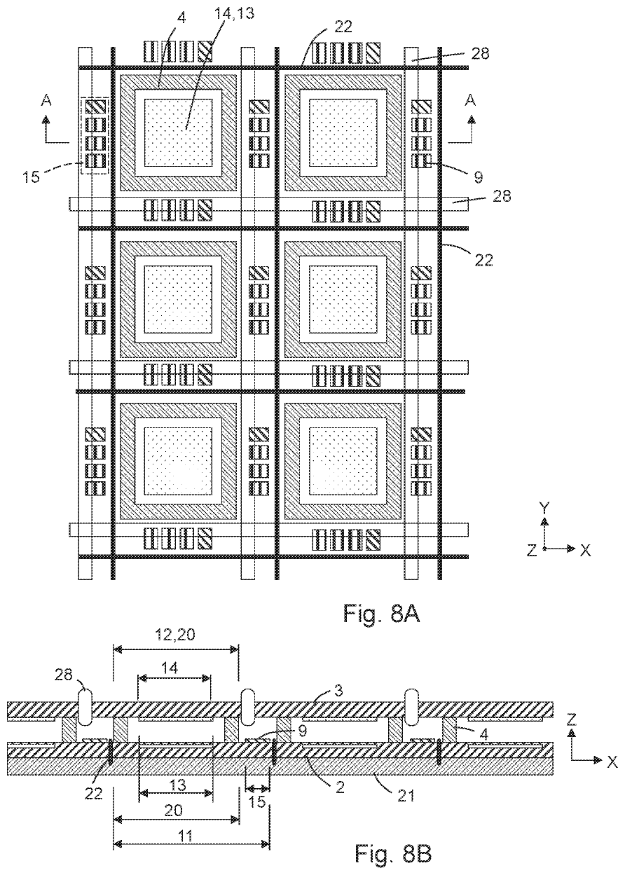

A method of manufacturing infrared sensor 1 according to the sixth embodiment will next be described. Explanations regarding steps and effects that are the same as those in the first embodiment is here omitted. FIG. 8A is a plan view of stacked substrate 16 in which first substrate 2 and second substrate 3 are stacked, and FIG. 8B is a cross-sectional view taken along line A-A in FIG. 8A. For convenience, FIG. 8B is a cross-sectional view along the X-direction, but this representation similarly applies to cross-sectional views along the Y-direction. Pad areas 15 are provided on the second substrate 3 side of first substrate 2. Two pad areas 15 are provided so as to face two adjacent sides of four peripheral sides of circuit area 13 of first substrate 2. In this embodiment, second substrate 3 is divided along dicing lines 28 by blade dicing or laser ablation dicing (dicing step). As seen a plan view from the Z-direction, one or more (in this embodiment, more than one) first modification lines 22 and one or more (in this embodiment, more than one) dicing lines 28 are formed at mutually different positions.

Blade dicing is performed in a state in which stacked substrate 16 is placed on a support stand (not shown). Therefore, the stretchable member attachment step may be performed after the dicing step, followed by the first modification line formation step and dividing step. That is, the dividing step may be performed after the dicing step. This embodiment may be applied when, as seen in a plan view from the Z-direction, the length that each second functional part formation area 12 occupies in the X-direction (a direction perpendicular to relevant second modification line 23) is shorter than the length that each first functional part formation area 11 occupies in the X-direction. This embodiment is the same as the first embodiment except that second modification lines 23 are replaced with dicing lines 28, with the result that the configuration of infrared sensor 1 is also almost the same as in the first embodiment. In other words, infrared sensor 1 obtained in this embodiment is almost the same as that shown in FIG. 1. However, since second substrate 3 is cut by blade dicing in infrared sensor 1 of this embodiment, the length of second projecting portion 19 in the X-direction in FIG. 1 is shorter than that of the first embodiment by the width of the cutting allowance of blade dicing.

### Seventh Embodiment

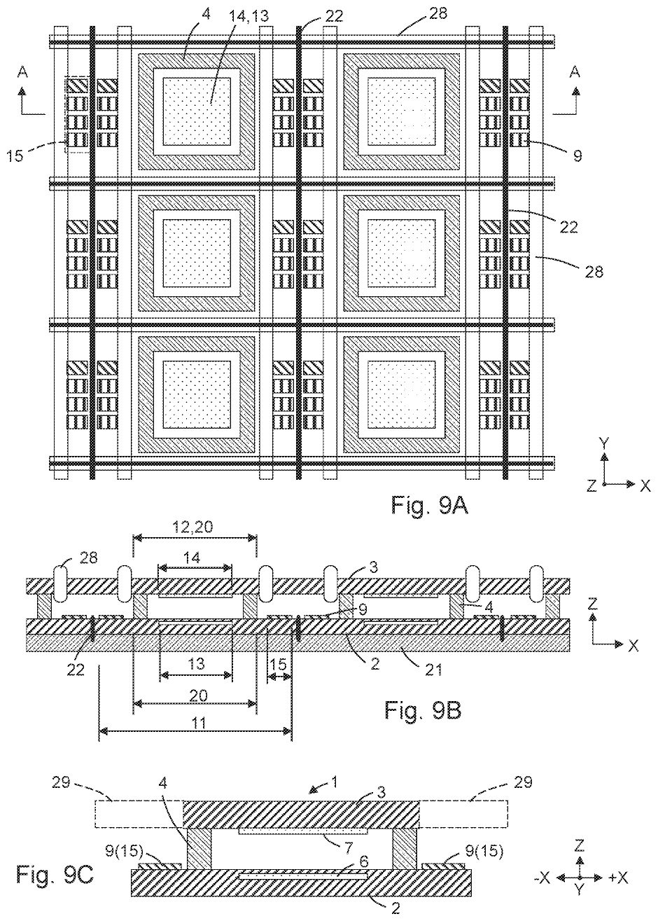

A method of manufacturing infrared sensor 1 according to the seventh embodiment will next be described. Explanations regarding steps and effects that are the same as those in the sixth embodiment is here omitted. Stacked substrate 16 of this embodiment is the same as that of the fourth embodiment. FIG. 9A is a plan view of stacked substrate 16 in which first substrate 2 and second substrate 3 are stacked, FIG. 9B is a cross-sectional view taken along line A-A in FIG. 9A, and FIG. 9C is a cross-sectional view of one infrared sensor 1 cut out from stacked substrate 16. Two pad areas 15 are provided so as to face, of the four peripheral sides of circuit area 13 of first substrate 2, two adjacent sides that face each other in the X-direction. In this embodiment as well, similar to the sixth embodiment, second substrate 3 is divided along dicing lines 28 by blade dicing or laser ablation dicing (dicing step). In a plan view from the Z-direction, one or more (in this embodiment, more than one) first modification lines 22 extending in the X-direction are formed to coincide with one or more (in this embodiment, more than one) dicing lines 28 extending in the X-direction. In a plan view from the Z-direction, one or more (in this embodiment, more than one) first modification lines 22 extending in the Y-direction are formed to coincide with one or more (in this embodiment, more than one) dicing lines 28 extending in the Y-direction are formed at mutually different positions.

In this embodiment as well, the dicing step may be performed in a state in which stacked substrate 16 is placed on a support stand, followed by the stretchable member attachment step, the first modification line formation step and the dividing step. This embodiment may be also applied when, as seen in a plan view from the Z-direction, the length that each second functional part formation area 12 occupies in the X-direction (a direction perpendicular to relevant second modification line 23) is shorter than the length that each first functional part formation area 11 occupies in the X-direction. In this embodiment, dicing lines 28 are provided on both sides in the X-direction of thermistor element area 14 of second substrate 3 for each infrared sensor 1. Since this portion 29 is removed in the dicing step, the laser beam is directly applied onto first substrate 2 from the second substrate 3 side without passing through second substrate 3 in the first modification line formation step.

### Modifications

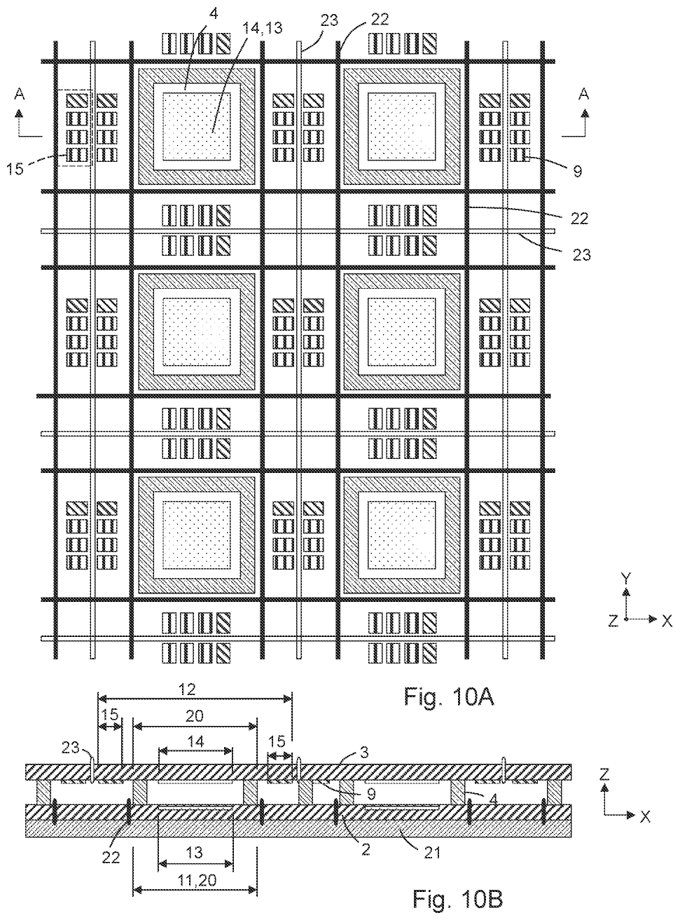

The number of pad areas 15 of each infrared sensor 1 is not limited. FIGS. 10A and 10B show a modification of the fourth embodiment. FIG. 10A is a plan view of stacked substrate 16 in which first substrate 2 and second substrate 3 are stacked, and FIG. 10B is a cross-sectional view taken along line A-A in FIG. 10A. For convenience, FIG. 10B is cross-sectional views along the X-direction, but these representations also apply to cross-sectional views along the Y-direction. Four pad areas 15 are provided facing the four peripheral surfaces of thermistor element area 14 of second substrate 3. In a plan view from the Z-direction, the length that each second functional part formation area 12 occupies in the X-direction is greater than the length that each first functional part formation area 11 occupies in the X-direction. Furthermore, in a plan view from the Z-direction, the length that each second functional part formation area 12 occupies in the Y-direction is greater than the length that each first functional part formation area 11 occupies in the Y-direction. In the modification shown in FIGS. 10A and 10B, for each infrared sensor 1, first modification lines 22 are formed on both sides in the X-direction and on both sides in the Y-direction of first functional part formation area 11. For this reason, the number of one or more (in this embodiment, more than one) first modification lines 22 extending in the Y-direction is greater than the number of one or more (in this embodiment, more than one) second modification lines 23 extending in the Y-direction, and the number of one (in this embodiment, more than one) first modification lines 22 extending in the X-direction is greater than the number of one or more (in this embodiment, more than one) second modification lines 23 extending in the X-direction. In addition, portions that are not used as infrared sensor 1 on the X-direction side and Y-direction side of infrared sensor 1 are generated in first substrate 2, but since these portions are held by stretchable member 21 after the dividing step, these portions can be easily removed.

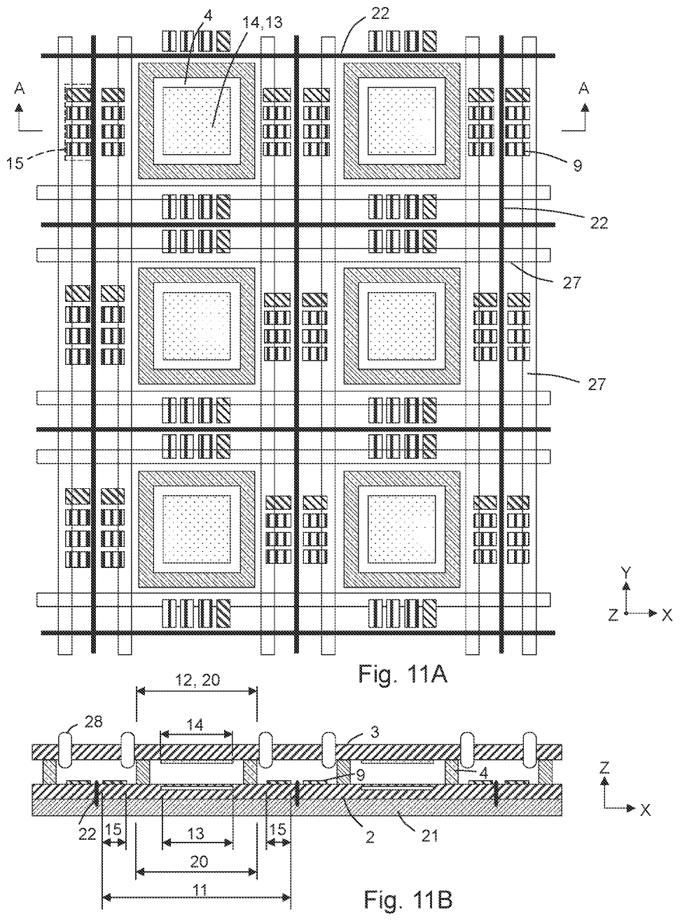

FIGS. 11A and 11B show a modification of the seventh embodiment. FIG. 11A is a plan view of stacked substrate 16 in which first substrate 2 and second substrate 3 are stacked, and FIG. 11B is a cross-sectional view taken along line A-A in FIG. 11A. For convenience, FIG. 11B is cross-sectional views along the X-direction, but these representations similarly apply to cross-sectional views along the Y-direction. Four pad areas 15 are provided facing the four peripheral sides of circuit area 13 of first substrate 2. In a plan view from the Z-direction, the length that each first functional part formation area 11 occupies in the X-direction is greater than the length that each second functional part formation area 12 occupies in the X-direction. Furthermore, in a plan view from the Z-direction, the length that each first functional part formation area 11 occupies in the Y-direction is greater than the length that each second functional part formation area 12 occupies in the Y-direction. In the modification shown in FIGS. 11A and 11B, for each infrared sensor 1, dicing lines 28 are provided on both sides in the X-direction and on both sides in the Y-direction of thermistor element area 14 of second substrate 3. For this reason, portions that are not used as infrared sensor 1 in the X-direction sides and Y-direction sides of infrared sensor 1 are generated in second substrate 3. Since these portions are removed in the dicing step, in the first modification line formation step, the laser beam is directly applied onto first substrate 2 from the second substrate 3 side without passing through second substrate 3.

In the first, second, third, and sixth embodiments, infrared sensors 1 have first projecting portions 18 and second projecting portions 19 projecting in opposite directions in the X-direction, and first projecting portions 18 and second projecting portions 19 projecting in opposite directions in the Y-direction. However, first projecting portions 18 and second projecting portions 19 may be provided only in either the X-direction or the Y-direction. Furthermore, in the first, second, third, fifth, and sixth embodiments, first and second modification lines 22 and 23 (or dicing lines 28) extending in the Y-direction and first and second modification lines 22 and 23 (or dicing lines 28) extending in the X-direction are similarly formed. However, depending on the arrangement of functional parts such as pad areas 15, first and second modification lines 22 and 23 (or dicing lines 28) extending in the Y-direction and first and second modification lines 22 and 23 (or dicing lines 28) extending in the X-direction may have different forms.

Although certain embodiments of the present disclosure have been shown and described in detail, it should be understood that various changes and modifications may be made without departing from the spirit or scope of the appended claims.

### LIST OF REFERENCE NUMERALS

1 infrared sensor (an example of an electronic device)
2 first substrate
3 second substrate
11 first functional part formation area
12 second functional part formation area
13 circuit area
14 thermistor element area
15 pad area
17 chips
18 first projecting portion
19 second projecting portion
21 stretchable member
22 first modification line
23 second modification line
28 dicing line

1. A method for manufacturing an electronic device comprising:
a stretchable member attachment step of attaching a stretchable member to a first substrate on which a second substrate is stacked;
a first modification line formation step of forming at least one first modification line by irradiating the first substrate with a laser beam; and
a dividing step of stretching the stretchable member to divide the first substrate along the at least one first modification line.

2. The method for manufacturing an electronic device according to claim 1, wherein: in the first modification line formation step, the at least one first modification line is formed by irradiating the first substrate with the laser beam from the second substrate side.

3. The method for manufacturing an electronic device according to claim 2, wherein: in the first modification line formation step, the at least one first modification line is formed by irradiating the first substrate with the laser beam transmitted through the second substrate.

4. The method for manufacturing an electronic device according to claim 1, wherein:
the first substrate has a first functional part formation area, the second substrate has a second functional part formation area; and
in a plan view from a direction in which the first substrate and the second substrate are stacked, a length the first functional part formation area occupies in one direction perpendicular to the first modification line is greater than a length the second functional part formation area occupies in the one direction.

5. The method for manufacturing an electronic device according to claim 1, wherein the first substrate has a pad area on a surface that faces the second substrate.

6. The method for manufacturing an electronic device according to claim 1, further comprising a second modification line formation step of forming at least one second modification line by irradiating the second substrate with a laser beam,
wherein, in the dividing step, the second substrate is divided along the at least one second modification line.

7. The method for manufacturing an electronic device according to claim 6, wherein:
the first substrate has a first functional part formation area, and the second substrate has a second functional part formation area; and
in a plan view from a direction in which the first substrate and the second substrate are stacked, a length the second functional part formation area occupies in one direction perpendicular to the second modification line is greater than a length the first functional part formation area occupies in the one direction.

8. The method for manufacturing an electronic device according to claim 6, wherein the second substrate has a pad area on a surface that faces the first substrate.

9. The method for manufacturing an electronic device according to claim 6, wherein:
in a plan view from a direction in which the first substrate and the second substrate are stacked, the at least one first modification line and the at least one second modification line are formed at different positions from each other.

10. The method for manufacturing an electronic device according to claim 9, wherein:
in the dividing step, a portion of the first substrate between one of the at least one first modification line and one of the at least one second modification line in the plan view becomes a part of one chip; and
a portion of the second substrate between the one first modification line and the one second modification line in the plan view becomes a part of another chip.

11. The method for manufacturing an electronic device according to claim 6, wherein the number of the at least one first modification line is greater than the number of the at least one second modification line.

12. The method for manufacturing an electronic device according to claim 1, further comprising a dicing step of dividing the second substrate by blade dicing or laser ablation dicing,
wherein the dividing step is performed after the dicing step.

13. The method for manufacturing an electronic device according to claim 1, further comprising a dicing step of dividing the second substrate along at least one dicing line by blade dicing or laser ablation dicing, wherein:
in a plan view from a direction in which the first substrate and the second substrate are stacked, the at least one first modification line and the at least one dicing line are formed at different positions from each other; and
in the dividing step, a portion of the first substrate between one of the at least one first modification line and one of the at least one dicing line in the plan view becomes a part of one chip; and
a portion of the second substrate between the one first modification line and the one dicing line in the plan view becomes a part of another chip.

14. An electronic device comprising:
a first substrate; and
a second substrate stacked with the first substrate, wherein:
in a plan view from a direction in which the first substrate and the second substrate are stacked, the first substrate has a first projecting portion that projects from the second substrate in a first direction, and the second substrate has a second projecting portion that projects from the first substrate in a direction opposite to the first direction; and
at least one of a surface of the first projecting portion that faces the second substrate and a surface of the second projecting portion that faces the first substrate has a pad region.
